(19) United States
(12) Patent Application Publication
(10) Pub. No.: US 2010/0007334 A1
(43) Pub. Date: Jan. 14, 2010

(54) POWER SOURCING EQUIPMENT DEVICE AND METHOD OF PROVIDING A POWER SUPPLY TO A POWERED DEVICE

(75) Inventor: Russell J. Apfel, Austin, TX (US)

Correspondence Address: SCHWEGMAN, LUNDBERG & WOESSNER, P.A., P.O. BOX 2938, MINNEAPOLIS, MN, 55402, US

(73) Assignee: Silicon Laboratories Inc., Austin, TX (US)

(21) Appl. No.: 12/169,077

(22) Filed: Jul. 8, 2008

(51) Int. Cl. G01R 19/00; G01R 1/30

(52) U.S. Cl. 324/123 R; 324/76.11

(57) ABSTRACT

In a particular embodiment, a power sourcing equipment (PSE) device includes a plurality of network ports adapted to communicate data and to selectively provide power to one or more powered devices via a plurality of channels. The PSE device further includes a plurality of sense elements, where each sense element is coupled to a respective network port of the plurality of network ports. The PSE also includes a power sensing circuit having an analog-to-digital converter (ADC) adapted to be selectively coupled to a selected network port of the plurality of network ports. The power sensing circuit selectively measures at least one electrical parameter associated with the selected network port.

### BACKGROUND

The present disclosure is generally related to a power sourcing equipment (PSE) device and method of providing a power supply to a powered device.

Power over Ethernet (PoE), which is outlined in IEEE Standard 802.3™-2005 clause 33 (the PoE standard), refers to a technique for delivering power and data to an electronic device via Ethernet cabling. In a PoE system, a power-sourcing equipment (PSE) device provides a power supply and data to electronic devices, which may be referred to as powered devices, via twisted pair wires of an Ethernet cable. A powered device is an electronic device that derives it power supply and receives data from the same cable. In a particular embodiment, a powered device is a PoE-enabled device. Such powered devices may include voice over Internet protocol (VoIP) telephones, wireless routers, security devices, field devices to monitor process control parameters, data processors, and the like. PoE, broadband over power lines (BPL), and other power/data delivery systems eliminate the need for a separate power source to deliver power to attached powered devices.

The PoE standard specifies that a PSE device perform a powered device detection operation to determine whether a device that is attached to an input/output (I/O) port of the PSE device is PoE-enabled (i.e., a powered device) before supplying power via the Ethernet cable. To perform a powered device detection operation, the PSE device applies a DC voltage (within a range of 2.8 to 10 Volts DC) or a current (within a range of approximately 100 μA to 390 μA) to pairs of wires of the Ethernet cable via an input/output (I/O) port and monitors the I/O port to detect a signal, such as a received current (Amps) or a received voltage (V) to detect a resistance within an expected range (e.g. between 19 and 26.5 K-ohms). The received signal can be referred to as a powered device signature. In a particular example, the PSE device detects a PoE-enabled device (the powered device) based on a measured Volt-Amp (VA) slope derived from the powered device signature. If the PSE device does not detect a valid device signature, the PSE device does not apply power to the I/O port.

Once a powered device has been detected at a particular I/O port of the PSE device, the PoE standard specifies that the PSE device may optionally perform a power classification operation to determine power requirements of the detected powered device. If the PSE device supports power classification, the PSE device applies a classification voltage (DC) to the I/O port associated with the detected powered device. The PSE device monitors the I/O port to detect a powered device classification signature and determines the powered device's power classification based on this classification signature. The power classification specifies an operating current and voltage requirement for the powered device. In a particular example, the PSE device is adapted to manage a power budget based on such power requirements.

Generally, the PSE devices for PoE solutions support multiple powered devices via multiple channels. In general, various PSE devices can support from four (4) to one hundred ninety-two (192) channels. In some instances, commercially available PSE devices may support a single channel, for example, for specialized applications. Commercially available PSE devices typically support four (4), eight (8), or twelve (12) lines, and their associated circuit boards may support twelve (12), twenty-four (24), or forty-eight (48) channels. Each of the multiple channels represents an I/O port.

To support powered device detection and classification and to support power supply protection specified by the PoE Standard, the PSE device is adapted to measure currents and voltages at each of the I/O ports. Line current measurements at each of the I/O ports can range from less than one milliamp (1 mA) for powered device detection to hundreds of milliamps for over-current protection. In some instances, the measure current can be as low as 0.1 mA for detection measurements, and for reasonable accuracy, the measurement resolution should be approximately 10 μA. Further, in some instances, the measured current can be as high as 400 mA to 800 mA, which gives a dynamic range of almost 100,000 to one or 17 data bits. Further, line voltage measurements at each of the I/O ports can range from a few volts for detection to around 50 volts for operating power supply voltage monitoring. Conventionally, PSE devices utilize multiple measurement circuits and/or complex analog circuits with multiple high-precision analog-to-digital (A/D) converters to provide measurements having a desired accuracy for the different measurements. Such circuitry can be expensive.

### SUMMARY

In a particular embodiment, a power sourcing equipment (PSE) device includes a plurality of network ports adapted to communicate data and to selectively provide power to one or more powered devices via a plurality of channels. The PSE device further includes a plurality of sense elements, where each sense element is coupled to a respective network port of the plurality of network ports. The PSE also includes a power sensing circuit having an analog-to-digital converter (ADC) adapted to be selectively coupled to a selected network port of the plurality of network ports. The power sensing circuit selectively measures at least one electrical parameter associated with the selected network port.

In another particular embodiment, a multi-channel circuit device is disclosed that includes a plurality of network ports adapted to communicate with one or more powered devices. The multi-channel circuit device further includes a power measurement circuit that can be selectively coupled to a selected network port of the plurality of network ports. The power measurement circuit is adapted to measure at least one electrical parameter of the selected network port. The power measurement circuit is adapted to measure a first output voltage of the selected network port within a first voltage range relative to a positive supply voltage during a powered device detection process and is adapted to measure a second output voltage within a second voltage range relative to the positive supply voltage during a powered device classification process.

In still another particular embodiment, a method of providing power to a powered device is disclosed that includes providing a power sourcing equipment (PSE) device including a plurality of network ports adapted to communicate power and data to a powered device. The PSE device includes a power measurement circuit including an adjustable gain amplifier and an analog-to-digital converter (ADC). The method further includes selectively coupling the power measurement circuit to a first selected network port of the plurality of network ports to measure at least one first electrical parameter associated with the first selected network port and selectively coupling the power measurement circuit to a second selected network port of the plurality of network ports to measure at least one second electrical parameter associated with the second selected network port.

### BRIEF DESCRIPTION OF THE DRAWINGS

FIG. 1 is a diagram of a particular illustrative embodiment of a Power over Ethernet (PoE) system including a multi-channel power sourcing equipment (PSE) device to provide power to a powered device;

FIG. 2 is a block diagram of a particular illustrative embodiment of a PoE system including a multi-channel power-sourcing equipment (PSE) device to provide power to a powered device;

FIG. 3 is a diagram of a particular illustrative embodiment of a portion of a shared measurement circuit of a multi-channel PSE device to provide power to a powered device;

FIG. 4 is a diagram of a second particular illustrative embodiment of a portion of a shared measurement circuit of a multi-channel PSE device to provide power to a powered device;

FIG. 5 is a flow diagram of a particular illustrative embodiment of a method of providing power to a powered device;

FIG. 6 is a flow diagram of a second particular illustrative embodiment of a method of providing power to a powered device; and

FIG. 7 is a flow diagram of a third particular illustrative embodiment of a method of providing power to a powered device.

### DETAILED DESCRIPTION OF ILLUSTRATIVE EMBODIMENTS

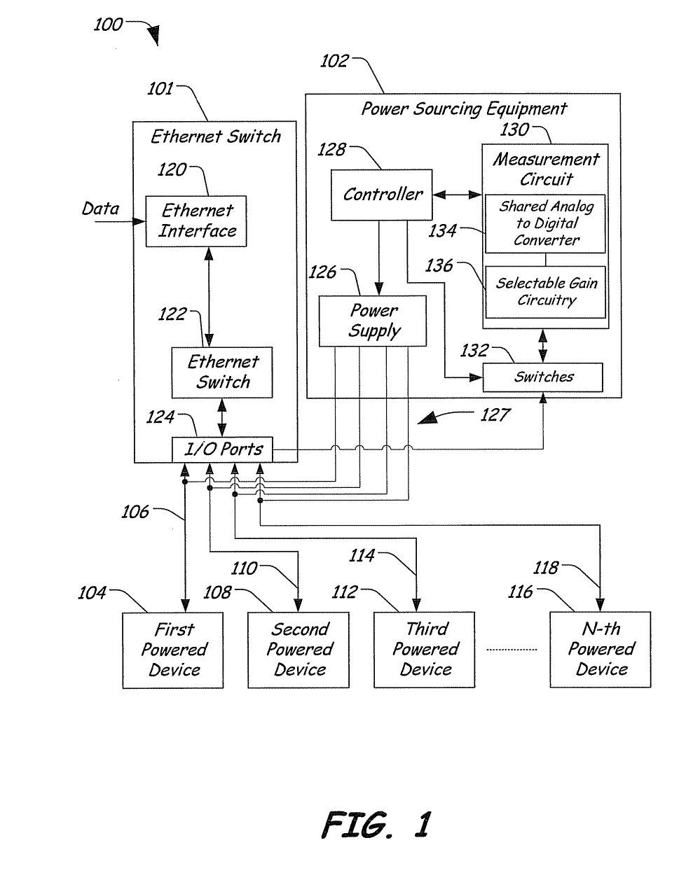

FIG. 1 is a diagram of a particular illustrative embodiment of a Power over Ethernet (PoE) system 100 including an Ethernet switch device 101 and a power sourcing equipment (PSE) device 102. The Ethernet switch device 101 is coupled to to one or more powered devices, such as powered devices 104, 108, 112, and 116, via first, second, third and N-th cables 106, 110, 114, and 118. Further, the PSE device 102 is coupled to the first powered device 104 via the first cable 106, to the second powered device 108 via the second cable 110, to the third powered device 112 via the third cable 114, and to an N-th powered device 116 via the N-th cable 118. In a particular embodiment, the PSE device 102 and the Ethernet switch device 101 can be provided within a single electronic device. In another particular embodiment, the Ethernet switch device 101 can provided data to the powered devices 104, 108, 112, and 116 via the cables 106, 110, 114, and 118, and the PSE device 102 can be a mid-span type device that is adapted to inject power onto the cables 106, 110, 114, and 118 to power the one or more powered device 104, 108, 112, and 116. In a particular embodiment, the first, second, third, and N-th cables 106, 110, 114, and 118 are Ethernet cables and the first, second, third, and N-th powered devices 104, 108, 112, and 116 are PoE-enabled devices that are adapted to receive power and data via the Ethernet cables 106, 110, 114, and 118. While only four (4) powered devices are shown, it should be understood that the PSE device 102 is adapted to communicate power to any number of powered devices.

The Ethernet switch 101 includes an Ethernet Interface 120 that is responsive to a network uplink to send and receive data. The Ethernet Interface 120 is coupled to an Ethernet switch circuit 122, which is coupled a plurality of input/output (I/O) ports 124 to route data packets to the first, second, third, and N-th powered devices 104, 108, 112, and 116 via the I/O ports 124. The PSE device 102 includes a power supply circuit 126, which is coupled to the plurality of I/O ports 124 and which is controlled by a controller 128. The controller 128 is coupled to a measurement circuit 130 and to a plurality of switches 132. The controller 128 is adapted to selectively activate a selected switch of the plurality of switches 132 to couple the measurement circuit 130 to a selected I/O port of the plurality of I/O ports 124. Using the plurality of switches 132, the measurement circuit 130 can be shared by the plurality of I/O ports 124. Further, the controller 128 is adapted to control the power supply circuit 126 to provide a controlled power supply to a selected I/O port of the plurality of I/O ports 124 via the power supply connections 127.

The measurement circuit 130 includes a shared analog-to-digital converter (ADC) 134 and selectable gain circuitry 136, which allow the ADC 134 to be used to perform multiple measurements of various signals having different voltage ranges. The controller 128 is adapted to adjust a gain characteristic associated with the selectable gain circuitry 136 to achieve a desired gain, which may be used to scale a received signal. In a particular embodiment, the shared ADC 134 can be a low-resolution ADC circuit having a resolution of 10 bits or less, for example, and the selectable gain circuitry 136 can be used to scale a received signal so that the low-resolution ADC circuit 134 can provide an accurate digital output related to the received signal.

In a particular illustrative embodiment, the controller 128 is adapted to selectively activate a switch of the plurality of switches 132 to couple the measurement circuit 130 to a first I/O port that is coupled to the first powered device 104 via the first cable 106. The controller 128 is adapted to adjust a gain associated with selectable gain circuitry 136 of the measurement circuit 130 and to control the power supply 126 to apply a powered device detection signal to the first I/O port. The measurement circuit 130 measures a powered device detection signature, such as a current drawn by the first powered device 104 in response to the applied power detection signal. The controller 128 may be adapted to adjust the gain characteristic associated with the selectable gain circuitry 136 and to control the power supply 126 to apply a powered device classification signal to the first I/O port. The measurement circuit 130 is adapted to measure a classification signature associated with the first powered device 104 via the first I/O port in response to the applied powered device classification signal. Additionally, the measurement circuit 130 may adjust a gain characteristic associated with the selectable gain circuit 136 to monitor the first I/O port. The controller 128 controls the power supply 126 to provide power to the first powered device 104 via the first I/O port according to the classification signature.

In a particular embodiment, the PSE device 102 is adapted to use the measurement circuit 130 to selectively measure selected I/O ports of the plurality of I/O ports 124. Further, the PSE device 102 can use the measurement circuit 130 to monitor a power supply provided via each of the plurality of I/O ports 124 by periodically measuring the power supplied via the I/O ports to detect when a powered device is disconnected, for example. In a particular example, the PSE device 102 is adapted to monitor the power supply to detect a power event, such as an overvoltage or over-current condition where the voltage or current exceeds a predetermined threshold. The PSE device 102 is adapted to disable the power supply in response to detection of the power event.

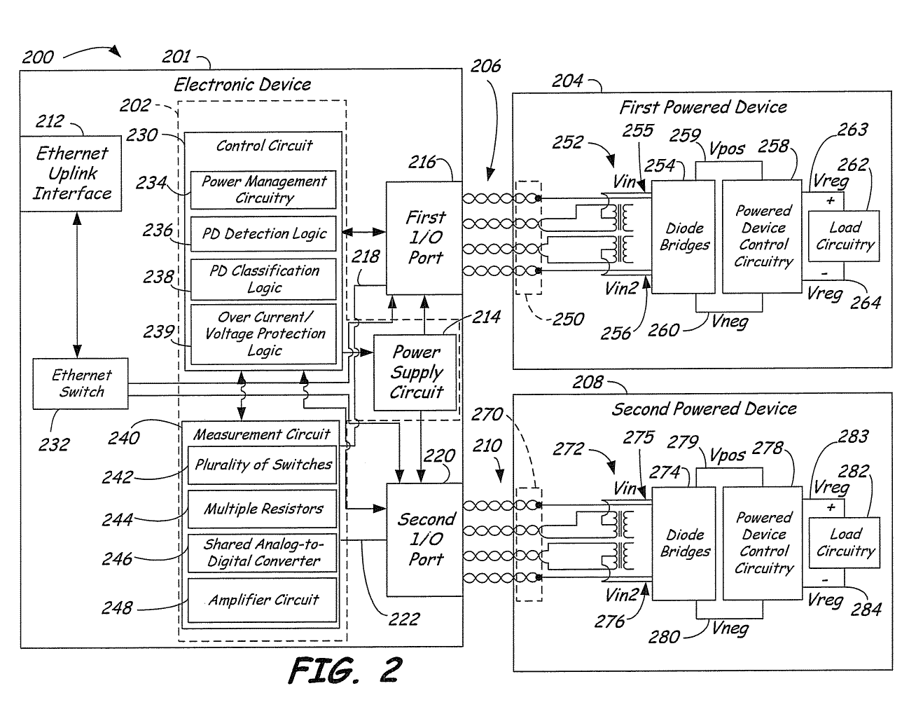

FIG. 2 is a block diagram of a particular illustrative embodiment of a Power over Ethernet (PoE) system 200 including an electronic device 201 that has an Ethernet uplink interface 212 coupled to an Ethernet switch 232. The electronic device 201 also includes a multi-channel power-sourcing equipment (PSE) device 202. The electronic device 201 is coupled to a first powered device 204 via a network cable 206 and to a second powered device 208 via a second network cable 210. The first and second network cables 206 and 208 include multiple twisted-pairs of wires, which twisted pairs can carry power, data, or any combination thereof.

The Ethernet uplink interface 212 is adapted to receive data from a network router (not shown), and the Ethernet switch 232 is adapted to communicate data to input/output (I/O) ports, such as the I/O ports 216 and 220. In a particular example, the Ethernet switch 232 is adapted to receive and route Ethernet packets between the Ethernet uplink interface 212 and the first and second powered devices 204 and 208. In general, it should be understood that the Ethernet switch 232, the Ethernet uplink interface 212, and the I/O ports 216 and 220 can be provided via a separate circuit device, and the PSE device 202 can be coupled to the cables 206 and 210, either via the I/O ports 216 and 220, adjacent to the I/O ports 216, 220, or at a midspan location along the cables 206 and 210.

The PSE device 202 includes a control circuit 230 to control operation of the PSE device 202. The PSE device 202 further includes a power supply circuit 214 that is coupled to a first input/output (I/O) port 216, which is coupled to the first powered device 204 via the first network cable 206. The power supply circuit 214 is also coupled to a second I/O port 220 that is coupled to the second powered device 208 via the second network cable 210. The control circuit 230 is adapted to control the power supply circuit 214 via control signals to provide controlled power supplies to the first and second powered devices 204 and 208. The PSE device 202 also includes a measurement circuit 240 that is coupled to the first and second I/O ports 216 and 220 and to the control circuit 230.

The control circuit 230 includes power management circuitry 234 that is adapted to manage an overall power budget for the PSE device 202. The power management circuitry 234 is also adapted to control the power supply circuit 214 to provide power to the first and second powered devices 204 and 208. The control circuit 230 further includes powered device (PD) detection logic 236 to detect a powered device coupled to the first or second I/O ports 216 and 220 based on a device signature that represents a resistance in a range from approximately 19 kΩ to 25.6 kΩ.

The control circuit 230 further includes powered device classification logic 238, which is adapted to determine a power classification associated with a powered device. The power classification determines a power requirement for the powered device, such as the first powered device 204. The power management circuitry 234 can manage its power budget based on the determined power classification. In a particular example, the PSE device 202 compares the power requirement associated with the power classification to an available power budget. When the available power budget is greater than the power requirement, the PSE device 202 provides power to the first powered device 204 and subtracts the power requirement associated with the first powered device 204 from the available power budget. When the available power budget is less than the power requirement, the PSE device 202 does not provide power to the first powered device 204.

The control circuit 230 also includes over current/over voltage protection logic 239 that is adapted to detect a power fault condition associated with one or more of the I/O ports, such as the first and second I/O ports 216 and 220. In a particular example, a power event can be detected when a power supply (voltage, current, or any combination thereof) exceeds a predetermined threshold. In a particular embodiment, the power event can be an overvoltage (a voltage level that exceeds a voltage threshold), an over-current (a current level that exceeds a threshold current), a power surge (such as an electrostatic discharge (ESD) event), or any combination thereof.

The measurement circuit 240 includes a plurality of switches 242 that are adapted to couple an amplifier circuit 248 and a shared analog-to-digital converter 246 to a selected I/O port, such as the first I/O port 216. The measurement circuit 240 further includes multiple resistors 244 that can be selectively coupled to an output of the amplifier circuit 248 to adjust a gain characteristic associated with the amplifier circuit 248 to scale a measurement signal. In a particular example, the shared analog-to-digital converter (ADC) 246 is a low-resolution ADC that has a resolution of 10 bits or less. By adjusting a gain associated with the amplifier circuit 248 (e.g., by selectively coupling one or more of the multiple resistors 244 to the amplifier circuit 248), the low-resolution ADC 246 can be used without sacrificing measurement precision. In a particular example, the measurement signal is scaled to achieve a desired accuracy using the low-resolution ADC 246.

The first powered device 204 includes a network interface 250, which may be an RJ-45 connector or another connector, to physically couple the first powered device 204 to the first network cable 206. The first powered device 204 further includes a pair of transformers 252, which are coupled to two pairs of the twisted pair wires of the first network cable 206. The other pairs of the twisted pair wires of the first network cable 206 and center taps from the pair of transformers 252 are first and second inputs (Vin and Vin2) 255 and 256 to a pair of diode bridges 254. Since power may be transmitted to the first powered device 204 via any of the twisted pair wires of the network cable 206, the pair of diode bridges 254 may be used to rectify the input power supply and to provide the power supply to powered device control circuitry 258 via positive and negative supply terminals (Vpos and Vneg) 259 and 260. The powered device control circuitry 258 may include a switching regulator to provide a regulated power supply to load circuitry 262 via positive and negative regulated terminals (Vreg+ and Vreg−) 263 and 264.

The second powered device 208 includes a network interface 270, which may be an RJ-45 connector or another connector, to physically couple the second powered device 208 to the second network cable 210. The second powered device 208 further includes a pair of transformers 272, which are coupled to two pairs of the twisted pair wires of the second network cable 210. The other pairs of the twisted pair wires of the second network cable 210 and center taps from the pair of transformers 272 are first and second inputs (Vin and Vin2) 275 and 276 to a pair of diode bridges 274. Since power may be transmitted to the second powered device 208 via any of the twisted pair wires of the network cable 210, the pair of diode bridges 274 may be used to rectify the input power supply and to provide the power supply to powered device control circuitry 278 via positive and negative supply terminals (Vpos and Vneg) 279 and 280. The powered device control circuitry 278 may include a switching regulator to provide a regulated power supply to load circuitry 282 via positive and negative regulated terminals (Vreg+ and Vreg−) 283 and 284.

In general, the PoE standard specifies a specific pair-to-pair resistance (powered device signature) that can be used to identify a device that can accept a power supply via its Ethernet connection (i.e., a powered device). In a particular embodiment, during a powered device detection process, the control circuit 230 controls the power supply circuit 214 to apply a voltage between 2 volts and 10 volts to a selected I/O port, such as the first I/O port 216. If a powered device is connected to the selected I/O port, the powered device detection logic 236 detects a current that reflects the presence of resistor having a resistance value of approximately 25 kΩ. In a particular embodiment, the powered device detection logic 236 recognizes the presence of the first powered device 204 coupled to the first I/O port 216 upon detection of a resistance that is within a range of 19 kΩ to 26.5 kΩ. In a particular embodiment, the powered device detection logic 236 may be adapted to detect the presence of the first powered device 204 upon detection of a resistance that is below 19 kΩ or above 26.5 kΩ, depending on the implementation. In a particular example, the PSE device 202 can test for the signature resistance by applying a voltage and measuring a current, by applying a current and measuring a voltage, by applying a signal and monitoring for a reflected signal indicating an impedance mismatch corresponding to the device signature, or any combination thereof. In a particular example, the ten (10) volt power supply applied to the I/O port results in a measured current within a range from 100 μA to 400 μA.

In a particular embodiment, during a powered device detection process, the control circuit 230 selectively activates at least one of the plurality of switches 242 to couple the first I/O port 216 to the measurement circuit 240. The control circuit 230 also selectively activates at least one of the plurality of switches 242 to couple one or more of the multiple resistors 244 to the amplifier circuit 248 to provide a first gain characteristic. The control circuit 230 controls the power supply circuit 214 to apply a detection voltage to the first I/O port 216. The measurement circuit 240 provides a powered device detection measurement, which is used by the powered device detection logic 236 to detect the first powered device 204.

The PoE standard also defines an optional power classification process that can be used to determine a power requirement for a particular powered device. Currently, the PoE standard defines four power classifications; however, a PoE Plus standard has been proposed that defines additional power classifications. Generally, the controller circuit 230 controls the power supply circuit 214 to apply a powered device classification voltage to the first I/O port 216. In a particular embodiment, the powered device classification voltage can be a voltage of approximately 20 volts. In another particular embodiment, the powered device classification voltage can include one or more voltage pulses. The measurement circuit 240 is adapted to measure a powered device classification signature at the first I/O port 216. In a particular example, the powered device classification signature may be a current at a particular current level that corresponds to a powered device classification defined by the PoE standard or the PoE Plus standard.

After detecting the first powered device 204, the control circuit 230 is adapted selectively activate at least one of the plurality of switches 242 to couple one or more of the multiple resistors 244 to the amplifier circuit 248 to adjust the gain characteristic of the amplifier circuit 248. Further, the control circuit 248 is adapted to control the power supply circuit 214 to apply a classification voltage to the first I/O port 216. The measurement circuit 240 provides a powered device classification measurement, which is used by the powered device detection logic 236 to determine a power classification associated with the first powered device 204. The power classification is related to a power requirement desired by the first powered device 204 for operation.

The PSE device 202 uses the power management circuitry 234 to determine whether the power requirement of the first powered device 204 is within a power budget of the PSE device 202. When the power requirement is within the power budget of the PSE device 202, the control circuit 230 controls the power supply circuit 214 to provide a power supply to the first powered device 204 according to the determined power classification. In a particular embodiment, the PSE device 202 is adapted to provide a 44 v to 57 v direct current (DC) power supply to the first powered device 204 and to the second powered device 208 via the first and second I/O ports 216 and 220.

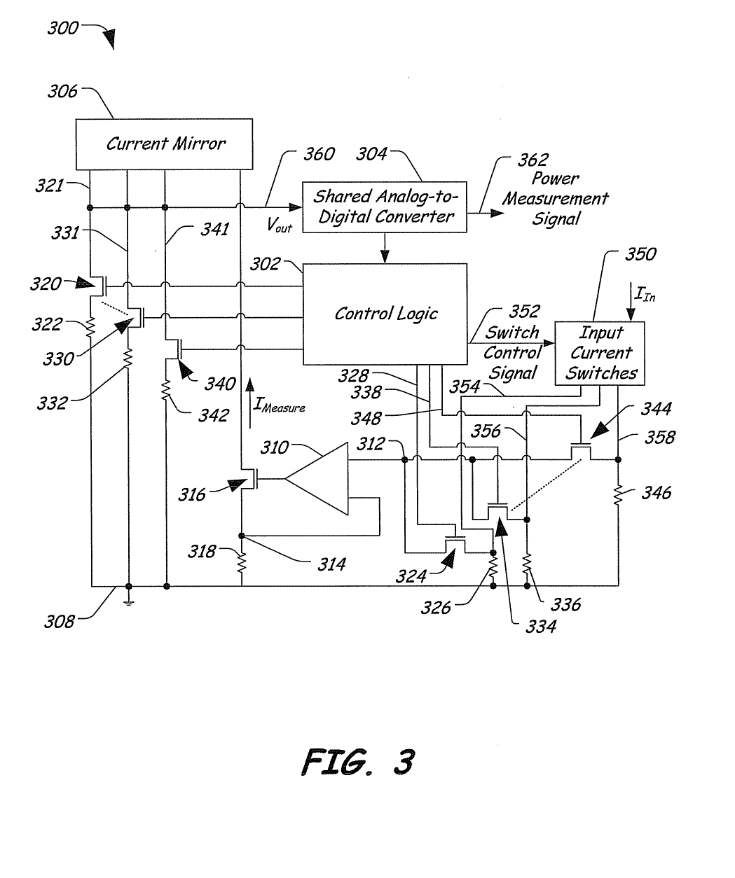

FIG. 3 is a diagram of a particular illustrative embodiment of a measurement circuit 300 of a multi-channel PSE device. The circuit device 300 includes control logic 302 that is coupled to a shared analog-to-digital converter (ADC) 304. Additionally, the control logic 302 is coupled to multiple input current switches 350 via a control line 352. Each switch of the multiple input current switches 350 is coupled to a respective input/output (I/O) port of a power sourcing equipment (PSE) device. The control logic 302 is adapted to selectively activate an input current switch of the multiple input current switches 350 to apply an input current (I_{In}) to one or more resistors, such as the sense resistors 326, 336, and 346, via lines 354, 356, and 358. The control logic 302 is also coupled to control terminals 328, 338, and 348 of a plurality of sense resistor switches 324, 334, and 344 to selectively couple one or more of the sense resistors 326, 336, and 346 to a first input node 312 of an amplifier 310. The amplifier 310 includes a second input coupled to a node 314. The node 314 is also coupled to a power supply terminal 308 via a resistor 318. The amplifier 310 further includes an output coupled to a control terminal of an amplifier output switch 316, which can be activated by the amplifier 310 to provide a measurement current (I_{Measure}) to a current mirror 306.

The current mirror 306 mirrors the measurement current (I_{Measure}) at first, second, and third lines 321, 331, and 341. The measurement circuit 300 further includes a first output resistor 322 that is coupled to the first line 321 via a first output switch 320. The first output resistor 322 is also coupled to the power supply terminal 308. The measurement circuit 300 further includes a second output resistor 332 that is coupled to the second line 331 via a second output switch 330 and that is coupled to the power supply terminal 308. Additionally, the measurement circuit 300 includes a third output resistor 342 that is coupled to the third line 341 via a third output switch 340. The third output resistor 342 is also coupled to the power supply terminal 308. The shared ADC 304 is coupled to the first, second, and third lines 321, 331, and 341 via a measurement line 360. The shared ADC 304 is adapted to receive a signal related to the measurement current (I_{Measure}) and to generate a power control signal 362 that can be used by a power management circuit of the power sourcing equipment (PSE) device to control power delivery to a powered device.

In a particular embodiment, the control logic 302 is adapted to selectively activate one or more of the input current switches 350 via a switch control signal sent via line 352 to couple a selected input/output (I/O) port of the PSE device to the measurement circuit 300. The control circuit 302 also activates one or more of the output switches 320, 330, and 340 and one of more of the sense resistor switches 324, 334, and 344 to adjust a gain characteristic of the amplifier 310. In a particular example, the control logic 302 allows the amplifier 310 and the shared ADC 304 to be used to measure I/O port currents ranging from 100 μA to 750 mA and to measure I/O port voltages ranging from 2V to 50V or more.

In a particular example, the measurement current (I_{Measure}) is related to the input current (I_{In}) by the following equation:

I_{Measure}=I_{In}*(Rₛₑₙₛₑ/R_{Amp}) (Equation 1)

In this particular example, the input current (I_{In}) is coupled to the amplifier 310 via a selected input current switch of the input current switches 350. The sense resistor (Rₛₑₙₛₑ) represents a selected one of the resistors 326, 336, and 346, and the amplifier resistance (R_{Amp}) is represented by the resistor 318. Further, the resulting measurement current (I_{Measure}) can be converted to a voltage via a selected output resistor, such as the output resistors 322, 332, and 342 according to the following equation:

Vout=I_{In}*(Rₛₑₙₛₑ*R_{Amp})*R_{Out} (Equation 2)

where R_{Out} represents a selected output resistor of the output resistors 322, 332 and 342. Assuming that the output resistors 322, 332, and 342 have different resistances, the selection of the output resistor, such as the output resistor 322, can produce a voltage at the input to the shared ADC 304 and the selected sense resistor provides a desired gain so that the shared ADC 304 can be a relative low-resolution ADC having a resolution of eight (8) to ten (10) bits, for example.

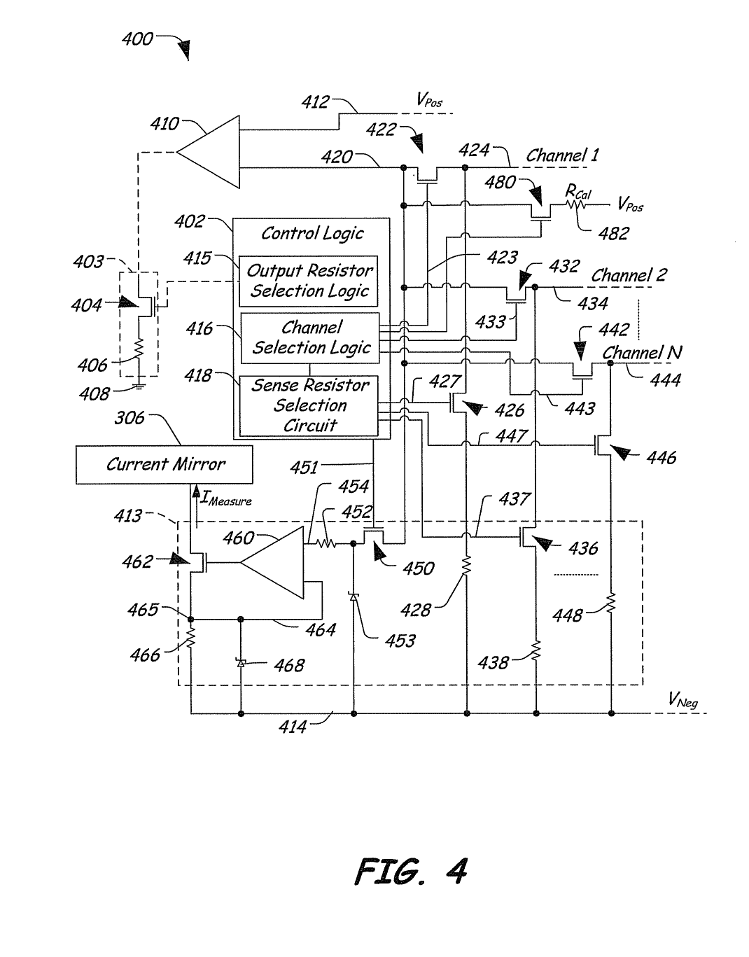

FIG. 4 is a diagram of a second particular illustrative embodiment of a measurement circuit 400 of a multi-channel PSE device to measure an output voltage relative to a negative power supply. In a particular example, the measurement circuit 400 can monitor power dissipation under normal operating conditions. The measurement circuit 400 includes a high voltage sense amplifier 410 that is coupled to a positive power supply terminal (Vpos) 412 and that is coupled to a negative power supply terminal (Vneg) 414 via an adjustable gain circuit 413. The measurement circuit 400 is adapted to sense a line voltage associated with a selected channel by converting a buffered voltage into a current with a large scale resistor, such as the sense resistors 428, 438 and 448, and then reconverting into a ground referenced output voltage using a selected output resistor from multiple selectable output resistors, generally indicated at 403.

The high voltage sense amplifier 410 includes a first input coupled to the positive power supply terminal (Vpos) 412 and a second input 420. The measurement circuit 400 also includes control logic 402. The control logic 402 includes output resistor selection logic 415 that is adapted to selectively activate one or more of the multiple output resistors 403. The control logic 402 further includes channel selection logic 416 to selectively couple a first channel (Channel 1) 424, a second channel (Channel 2) 434, and an N-th channel (Channel N) 444 to the second input 420 of the high voltage sense amplifier 410. The control logic 402 further includes a sense resistor selection circuit 418 to selectively couple a sense resistor to a desired channel, such as a sense resistor 428 to the first channel 424, a sense resistor 438 to the second channel 434, and an N-th sense resistor 428 to the N-th channel 444.

The measurement circuit 400 includes a first channel switch 422 including a first channel terminal coupled to the first channel 424, a first control terminal 423 coupled to the channel selection logic 416, and a first input terminal coupled to the second input 420 of the high voltage sense amplifier 410. The measurement circuit 400 further includes a second channel switch 432 including a second channel terminal coupled to the second channel 434, a second control terminal 433 coupled to the channel selection logic, and a second input terminal coupled to the second input of the high voltage sense amplifier 410. The measurement circuit 400 also includes an N-th channel switch 442 including an N-th channel terminal coupled to the N-th channel 444, an N-th control terminal 443 coupled to the channel selection logic 416, and an N-th input terminal coupled to the second input 420 of the high voltage sense amplifier 410.

In a particular embodiment, the first channel 424 is referenced to a negative power supply (V_{Neg}) 414 via a first sense resistor switch 426 and a first sense resistor 428. The first sense resistor switch 426 includes a first channel terminal coupled to the first channel 424, a control terminal 427 coupled to the sense resistor selection logic 418, and a sense resistor terminal coupled to the first sense resistor 428. The second channel 434 is referenced to the negative power supply (V_{Neg}) 414 via a second sense resistor switch 436 and a second sense resistor 438. The second sense resistor switch 436 includes a second channel terminal coupled to the second channel 434, a control terminal 437 coupled to the sense resistor selection logic 418, and a sense resistor terminal coupled to the second sense resistor 438. The N-th channel 444 is referenced to the negative power supply (V_{Neg}) 414 via an N-th sense resistor switch 446 and an N-th sense resistor 448. The N-th sense resistor switch 446 includes an N-th channel terminal coupled to the N-th channel 444, a control terminal 447 coupled to the sense resistor selection logic 418, and a sense resistor terminal coupled to the N-th sense resistor 448.

The measurement circuit 400 further includes a gain amplifier 460 having a first gain input 454 coupled to a resistor 452 that is coupled to a gain input terminal of a switch 450. In a particular embodiment, the resistor 452 may have a resistance of approximately 100 kΩ. The switch 450 includes a control terminal 451 that is coupled to the control logic 402 and includes a second gain terminal that is coupled to the second input 420 of the high voltage amplifier 410. The gain amplifier 460 also includes a second input 464 that is coupled to a node 465. A resistor 466 and a breakdown diode 468 are coupled in parallel between the node 465 and the negative power supply terminal (V_{Neg}) 414. In a particular example, the breakdown diode 468 is adapted to limit a voltage applied to the second input 464 of the gain amplifier 460. In a particular example, the breakdown diode 468 has a breakdown voltage of approximately 62 volts and is adapted to conduct current when a voltage differential across the breakdown diode 468 exceeds 62 volts. The gain amplifier 460 includes an output that is coupled to a control terminal of an output switch 462, which includes a first terminal coupled to the node 465 and a second terminal coupled to the current mirror 306, illustrated in FIG. 3. In a particular embodiment, the measurement current (Iₘₑₐₛᵤᵣₑ) may also be provided to the control logic 402.

The control logic 402 further includes output resistor selection logic 415 that is coupled the multiple selectable output resistors 403. In a particular example, the output resistor selection logic 415 is coupled to a control terminal of an output switch 404 that includes a first output terminal coupled to an output of the high voltage amplifier 410 and a second terminal coupled to a power supply terminal 408 via a output resistor 406. In a particular example, the power supply terminal 408 is an electrical ground terminal to provide a ground referenced output voltage.

In a particular example, the high voltage sense amplifier 410 senses a line voltage associated with a selected channel, such as the first channel 424 by converting the line voltage to an electrical current via the sense resistor 428 and then reconverting the electrical current to a ground referenced output voltage using a selected output resistor, such as the output resistor 406. In a particular embodiment, the first, second, and N-th sense resistors 428, 438, and 448 have large resistances to keep the electrical current relatively low and to reduce power consumption. In a particular embodiment, the first, second, and N-th sense resistors 428, 438, and 448 may be 1 MΩ resistors. In a particular example, the output resistor selection logic 415 is adapted to select an output resistor from the multiple selectable output resistors 403 (such as for a powered device detection process having a 0V to 10V scale) to have a resistance of approximately 80 kΩ, which gives a full scale of 800 mV. For powered device classification, the output resistor selection logic 415 is adapted to select an output resistor from the multiple selectable output resistors 403 to have a resistance of approximately 40 kΩ, while for full scale sensing, an output resistor of 10 kΩ is acceptable. In a particular example, a voltage differential between the positive power supply terminal (Vpos) 412 and one of the first, second, and N-th channels 422, 432, and 442 may range from zero volts to fifty volts (i.e., from 0 v to 50 v).

In a particular example, calibration can be performed for the measurement circuit 400 by selectively activating a calibration switch 480 to couple the positive supply terminal (Vpos) through a calibration resistor 482 to the second input 420 of the high voltage amplifier 410. The calibration switch 480 includes a control terminal that is coupled to the channel selection logic 416, allowing the control logic 402 to calibrate the measurements by coupling the first and second inputs 412 and 420 of the high voltage amplifier 410 to the positive supply terminal (Vpos) 412 and by calculating an offset value at the output of the high voltage amplifier 410.

In general, the measurement circuits 300 and 400 illustrated in FIGS. 3 and 4 allow two simple amplifiers and some selectable sense resistors and selectable output resistors to provide gain scaling and level shifting for measuring voltages and currents on a multi-channel PSE device using a single low-cost analog-to-digital converter (ADC). The offset calibration eliminates most errors and the gain scaling allows the use of a relatively low-resolution ADC having, for example, a resolution of 8 to 10 bits, instead of using a more expensive, higher resolution ADC having a resolution of 14 to 16 bits. By using a low resolution ADC, the measurements can be sampled at a higher sampling rate and the ADC can be shared across many channels and measurements. In a particular example, a low resolution ADC requires fewer data bits to complete a measurement, allowing more measurements to be taken in less time. The over-sampled data can be digitally processed using a processor to remove noise and to increase accuracy. In a particular example, the processor may be the controller 128 illustrated in FIG. 1, the control circuit 230 illustrated in FIG. 2, the control logic 302 illustrated in FIG. 3, the control logic 402 illustrated in FIG. 4, or any combination thereof. In another particular example, the processor may be a general-purpose processor that is adapted to execute processor-readable instructions to control power and measurement functionality within the PSE device.

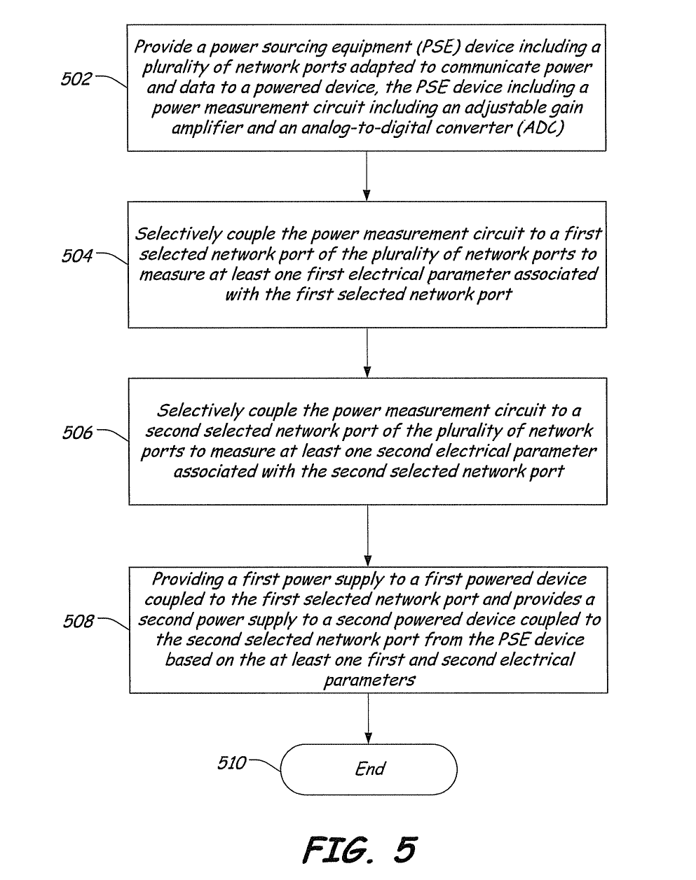

FIG. 5 is a flow diagram of a particular illustrative embodiment of a method of providing power to a powered device. At 502, a power sourcing equipment (PSE) device is provided that includes a plurality of network ports adapted to communicate power and data to a powered device. The PSE device includes a power measurement circuit including an adjustable gain amplifier and an analog-to-digital converter (ADC). In a particular example, the ADC is a low-resolution ADC having a resolution of 10 bits or less. Continuing to 504, the power measurement circuit is selectively coupled to a first selected network port of the plurality of network ports to measure at least one first electrical parameter associated with the first selected network port. In a particular example, the electrical parameter may be a current, a voltage, another electrical characteristic, or any combination thereof. In another particular example, the electrical parameter may be a powered device detection signature, a powered device classification signature, another signal, or any combination thereof.

Advancing to 506, the power management circuit is selectively coupled to a second selected network port of the plurality of network ports to measure at least one second electrical parameter associated with the second selected network port. Moving to 508, the PSE device provides a first power supply to a first powered device coupled to the first selected network port and provides a second power supply to a second powered device coupled to the second selected network port based on the at least one first and second electrical parameters. In a particular example, the at least one first and second electrical parameters represent power requirements of the first and second powered devices, respectively. The PSE device may have a limited power budget and may be adapted to selectively provide the first power supply, the second power supply, or any combination thereof based on an available power budget capacity. In another particular example, the first and second power supplies may have different voltage and current levels. The method terminates at 510.

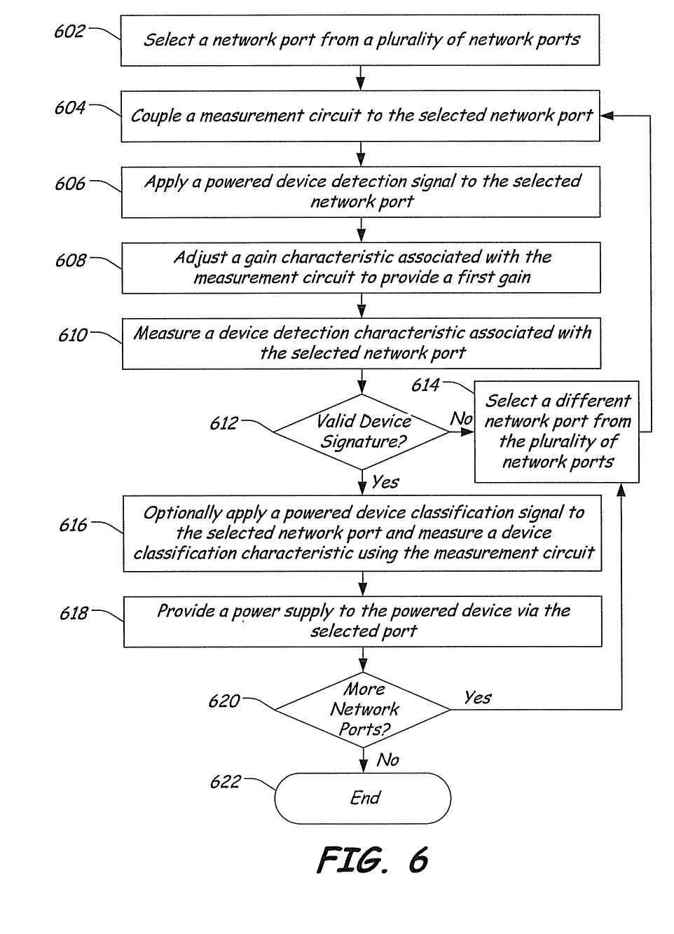

FIG. 6 is a flow diagram of a second particular illustrative embodiment of a method of providing power to a powered device. At 602, a network port is selected from a plurality of network ports. In a particular embodiment, the plurality of network ports may be associated with a power sourcing equipment (PSE) device that is adapted to provide power and data to powered devices via Ethernet cabling. Continuing to 604, a measurement circuit is coupled to the selected network port. Moving to 606, a powered device detection signal is applied to the selected network port. Advancing to 608, a gain characteristic associated with the measurement circuit is adjusted to provide a first gain. Proceeding to 610, a device detection characteristic that is associated with the selected network port is measured. In a particular example, the device detection characteristic may be a voltage, a current, another signal, or any combination thereof, which may be used by powered device detection logic to detect the presence of a Power over Ethernet (PoE) enabled device coupled to the selected network port.

Continuing to 612, the PSE device determines whether the measured device detection characteristic represents a valid device signature. If not, the method advances to 614 and a different network port is selected from the plurality of network ports. The method returns to 604 and the measurement circuit is coupled to the selected network port.

Returning to 612, if the measured device detection characteristic indicates a valid device signature, the method advances to 616 and a powered device classification signature is optionally applied to the selected network port and a device classification characteristic is measured using the measurement circuit. Continuing to 618, a power supply is provided to the powered device via the selected port. In a particular embodiment, the power supply is determined from a device classification defined by the PoE standard in view of the measured device classification characteristic. In another particular embodiment, if no device classification measurement is taken at 616, the power supply may be a default PoE power supply.

Continuing to 620, if there are more network ports, the method returns to 614 and a different network port is selected from the plurality of network ports. The method returns to 604 and the measurement circuit is coupled to the selected network port. Returning to 620, if there are no more network ports, the method advances to 622, and the method terminates.

In general, it should be understood that blocks 602-620 represent an illustrative embodiment of a process for performing powered device detection and optionally powered device classification. However, in some instances, a powered device may be coupled to a particular network port at a later time. Unused ports of a PSE device may be periodically polled to detect newly connected powered devices, to optionally classify the newly connected powered devices, and to provide power to the powered devices.

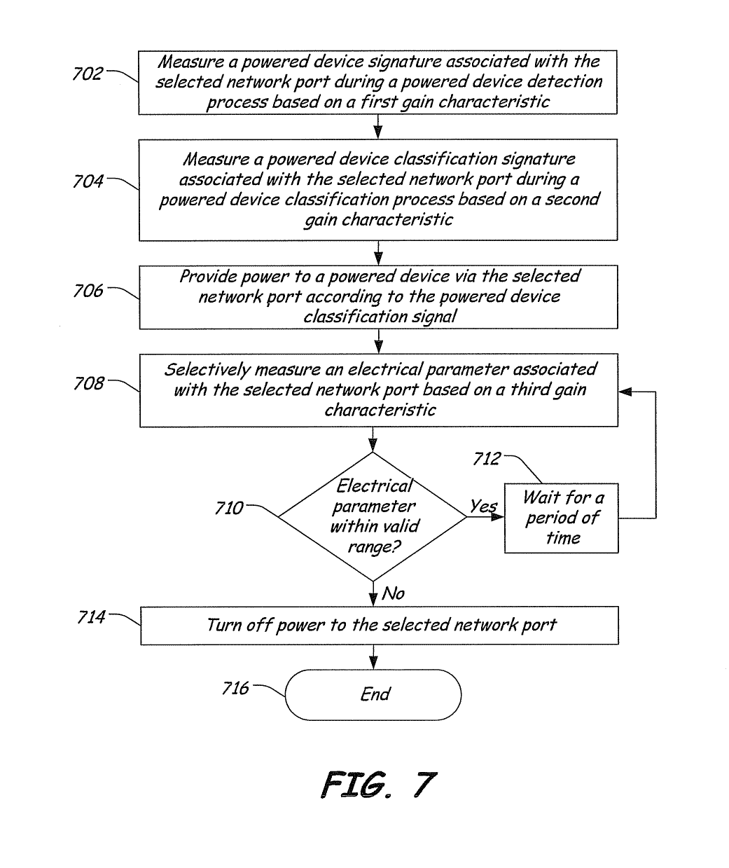

FIG. 7 is a flow diagram of a third particular illustrative embodiment of a method of providing power to a powered device. At 702, a powered device signature associated with the selected network port is measured during a powered device detection process based on a first gain characteristic. Continuing to 704, a powered device classification signature associated with the selected port is measured during a powered device classification process based on a second gain characteristic. Moving to 706, power is provided to a powered device via the selected network port according to the powered device classification signal. Proceeding to 708, an electrical parameter associated with the selected network port is selectively measured based on a third gain characteristic. Continuing to 710, if the electrical parameter is within a valid range, the method advances to 712 and the measurement circuit waits a period of time before returning to 708 and measuring again. Otherwise, at 710, if the electrical parameter is not with a valid range, the method advances to 714 and the power is turned off to the selected network port. In a particular example, the PSE device includes power management logic that is adapted to deactivate a power supply to the selected network port. The method terminates at 716.

In general, while the above-discussion has been largely directed to a Power over Ethernet (PoE) system including a power sourcing equipment (PSE) device to provide power and data to powered devices, it should be understood that the PSE device and method of providing power to powered devices may also be used with other types of power/data systems. For example, the PSE device may be adapted to provide power and data to powered devices via a broadband over power lines (BPL) implementation. In another particular example, the PSE device may be adapted for PoE, BPL, other power/data delivery systems, or any combination thereof. Further, while the above-discussion has been directed to the PoE standard, it is contemplated that the PoE standard and other power/data delivery standards may evolve over time. The PSE device disclosed herein can be adapted for use with such emerging standards, including the PoE plus standard.

Although the present invention has been described with reference to preferred embodiments, workers skilled in the art will recognize that changes may be made in form and detail without departing from the spirit and scope of the invention.

1. A power sourcing equipment (PSE) device comprising:
a plurality of network ports adapted to communicate data and to selectively provide power to one or more powered devices via a plurality of channels;
a plurality of sense elements, each sense element coupled to a respective network port of the plurality of network ports; and
a power sensing circuit including an analog-to-digital converter (ADC) adapted to be selectively coupled to a selected network port of the plurality of network ports, the power sensing circuit to selectively measure at least one electrical parameter associated with the selected network port.

2. The PSE device of claim 1, further comprising:
a plurality of switches, each of the plurality of switches coupled to the power sensing circuit and to a respective network port of the plurality of network ports; and
a control circuit coupled to the power sensing circuit to activate a selected switch to couple the ADC to the selected network port.

3. The PSE device of claim 2, further comprising:
a current mirror circuit:
a plurality of output switches, each output switch including a first terminal coupled to the current mirror circuit, a second terminal coupled to a power supply terminal through a resistor, and a control terminal responsive to the control circuit; and
an adjustable gain amplifier including an amplifier output coupled to the current mirror, a first input coupled to each of the plurality of switches, and a second input coupled to the amplifier output, the adjustable gain amplifier is responsive to selective activation of the selected switch from the plurality of switches by the control circuit to scale a signal associated with the at least one electrical parameter.

4. The PSE device of claim 2, wherein the power sensing circuit includes a level shifting circuit that is responsive to the control circuit to level shift a signal associated with the at least one electrical parameter from a first current level to a second current level.

5. The PSE device of claim 2, wherein the power sensing circuit further comprises a plurality of selectable output elements, and wherein the control circuit is adapted to select one or more of the plurality of selectable output elements to scale a signal associated with the at least one electrical parameter.

6. The PSE device of claim 5, wherein the plurality of selectable output elements comprise output resistors.

7. The PSE device of claim 1, further comprising a breakdown diode to limit a voltage at the selected network port relative to a voltage reference, wherein the power sensing circuit is adapted to measure the at least one electrical parameter relative to the voltage reference.

8. The PSE device of claim 7, wherein the voltage reference comprises a negative power supply.

9. The PSE device of claim 1, wherein the ADC comprises a low-resolution ADC circuit having a resolution of 10 bits or less.

10. The PSE device of claim 1, wherein the plurality of network ports are adapted to communicate with the one or more powered devices via Ethernet cables.

11. The PSE device of claim 1, wherein the plurality of sense elements comprise sense resistors.

12. A multi-channel circuit device comprising:
a plurality of network ports adapted to communicate with one or more powered devices;
a power measurement circuit adapted to be selectively coupled to a selected network port of the plurality of network ports and adapted to measure at least one electrical parameter of the selected network port, the power measurement circuit adapted to measure a first output voltage of the selected network port within a first voltage range relative to a positive supply voltage during a powered device detection process and adapted to measure a second output voltage within a second voltage range relative to the positive supply voltage during a powered device classification process.

13. The multi-channel circuit device of claim 12, wherein the power measurement circuit comprises a low-resolution analog-to-digital converter (ADC) circuit having a resolution of up to 10 bits.

14. The multi-channel circuit device of claim 13, wherein the power measurement circuit further comprises:
an amplifier circuit;
a plurality of selectable output gain setting elements;
a plurality of switches, each switch coupled to at least one output gain setting element to selectively couple the at least one output gain setting element to the amplifier circuit; and
a logic circuit to selectively activate one or more of the plurality of switches to adjust a gain associated with the amplifier circuit.

15. The multi-channel circuit device of claim 14, wherein the plurality of selectable output gain setting elements comprise a plurality of output resistors.

16. The multi-channel circuit device of claim 12, wherein the power measurement circuit comprises:
a positive supply terminal;
a negative output terminal associated with the plurality of network ports;
a plurality of output resistors;
a plurality of switches, each switch having a terminal associated with at least one output resistor of the plurality of output resistors; and
a high voltage sense amplifier to sense an output voltage, the high voltage sense amplifier including a first input coupled to the positive supply terminal, a second input coupled to the negative output terminal, and an output selectively coupled to at least one of a plurality output resistors, the high voltage sense amplifier configured to sense the output voltage by converting a differential voltage and the first and second inputs into a current using a large scale resistor and by re-converting the current to a ground referenced output voltage using a selected output resistor of the plurality of output resistors.

17. The multi-channel circuit device of claim 12, further comprising a clamp circuit to limit the differential voltage to a voltage level defined by a breakdown voltage of the clamp circuit.

18. The multi-channel circuit device of claim 12, wherein the first voltage range comprises a Power over Ethernet powered device detection voltage between approximately 2 volts to 10 volts and wherein the second voltage range comprises a Power over Ethernet powered device classification voltage of approximately 20 volts.

19. The multi-channel circuit device of claim 12, wherein the power measurement circuit is adapted to sense a third output voltage within a third voltage range during normal operation, wherein the third voltage range comprises a Power over Ethernet powered device operating voltage of approximately 0 volts to 50 volts.

20. A method of providing power to a powered device, the method comprising:
providing a power supply to one or more powered devices using a power sourcing equipment (PSE) device including a plurality of network ports adapted to communicate power and data to a powered device, the PSE device including a power measurement circuit including an adjustable gain amplifier and an analog- to-digital converter (ADC);
selectively coupling the power measurement circuit to a first selected network port of the plurality of network ports to measure at least one first electrical parameter associated with the first selected network port; and
selectively coupling the power measurement circuit to a second selected network port of the plurality of network ports to measure at least one second electrical parameter associated with the second selected network port.

21. The method of claim 20, further comprising:
providing a first power supply to a first powered device via the first selected network port according to the at least one first electrical parameter; and
providing a second power supply to a second powered device via the second selected network port according to the at least one second electrical parameter.

22. The method of claim 20, wherein the at least one electrical parameter comprises a detection parameter and a classification parameter, the method further comprising:
measuring a first detection parameter associated with the first selected network port via the power measurement circuit;
measuring a first classification parameter associated with the first selected network port via the power management circuit; and
providing an operating power supply to a powered device via the first selected network port according to a powered device classification defined by a power over Ethernet standard according to the first classification parameter.

23. The method of claim 20, wherein selectively coupling the power measurement circuit to a first selected network port of the plurality of network ports comprises:
selectively coupling an amplifier to the first selected network port;
selectively coupling a first output resistance to an output of the amplifier to achieve a first amplifier gain characteristic; and
generating a first digital output related to an analog input from the first selected network port, the first digital output comprising a first measurement.

24. The method of claim 23, further comprising:
selectively coupling a second output resistance to the output of the amplifier to achieve a second amplifier gain characteristic; and
generating a second digital output related to the analog input from the first selected network port, the second digital output comprising a second measurement.
